(19) United States
(12) Patent Application Publication
(10) Pub. No.: US 2026/0366144 A1
(43) Pub. Date: Nov. 19, 2026

(54) METHOD FOR FORMING A FILM HAVING AN AIR GAP AND APPARATUS FOR THE SAME

(71) Applicant: ASM IP Holding B.V., Almere (NL)

(72) Inventors: Shinya Yoshimoto, Tokyo (JP); Makoto Igarashi, Tokyo (JP)

(21) Appl. No.: 19/675,737

(22) Filed: May 13, 2026

Related U.S. Application Data
(60) Provisional application No. 63/806,760, filed on May 16, 2025.

(51) Int. Cl. C23C 16/04; C23C 16/46; C23C 16/52; H10W 10/00

(52) U.S. Cl. CPC C23C 16/045; C23C 16/46; C23C 16/52; H10W 10/021

(57) ABSTRACT

A method for forming a film having an air gap is provided. The method includes providing a substrate in a reaction chamber. The substrate includes a horizontal surface and a first gap feature extending downwardly from the horizontal surface. The method includes depositing a film on the horizontal surface and in the first gap feature through a deposition process. The film includes a first top surface on the first gap feature. The method includes performing a curing process on the film to form a first air gap in the film in the first gap feature.

### CROSS-REFERENCE TO RELATED APPLICATIONS

This application claims priority to U.S. Provisional Patent Application Ser. No. 63/806,760 filed May 16, 2025 titled METHOD FOR FORMING A FILM HAVING AN AIR GAP AND APPARATUS FOR THE SAME, the disclosure of which is hereby incorporated by reference in its entirety.

### BACKGROUND

### Technical Field

The present disclosure is related to a method for forming a film. More particularly, it is related to a method for forming a film having an air gap.

### BACKGROUND

Integrated circuits are typically manufactured by complex, multi-step processes in which various layers of materials are sequentially constructed in a predetermined arrangement on a substrate. Thus, earlier processing steps can have significant impacts on later steps, and the effects of deviations from expected parameters (e.g., thickness, density, uniformity) can compound these impacts. Accordingly, it is important that the layers be of high quality. For example, voids, thickness non-uniformity, and other defects in a layer can cause significant problems and can reduce device yield.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY

This summary is provided to introduce a selection of concepts in a simplified form. These concepts are described in further detail in the detailed description of embodiments of the disclosure below. This summary is not intended to identify key features or essential features of the claimed subject matter, nor is it intended to be used to limit the scope of the claimed subject matter.

According to some embodiments of the present disclosure, a method for forming a film having an air gap is provided. The method includes providing a substrate in a reaction chamber. The substrate includes a horizontal surface and a first gap feature extending downwardly from the horizontal surface. The method includes depositing a film on the horizontal surface and in the first gap feature through a deposition process. The film includes a first top surface on the first gap feature. The method includes performing a curing process on the film to form a first air gap in the film in the first gap feature.

In some embodiments, the curing process includes a plasma curing process.

In some embodiments, the plasma curing process includes a H₂ plasma curing process.

In some embodiments, the plasma curing process includes a curing depth extending from the first top surface of the film to the first gap feature, and the curing depth is about 2 nm to about 10 nm.

In some embodiments, the curing process includes a UV curing process.

In some embodiments, the UV curing process includes an excimer molecule.

In some embodiments, the excimer molecule includes Xe₂, NeF, Ar₂, Kr₂, F₂, ArBr, ArCl, KrI, ArF, KrBr, KrCl, or a combination thereof.

In some embodiments, the wavelength of the UV curing process is about 172 nm.

In some embodiments, the UV curing process includes a curing depth extending from the first top surface of the film to the first gap feature, and the curing depth is about 50 nm to about 100 nm.

In some embodiments, the deposition process further includes depositing the film to reach a second top surface on the first gap feature, and the second top surface is higher than the first top surface.

In some embodiments, the curing process is performed to increase the height of the first air gap.

In some embodiments, the substrate further includes a second gap feature extending downwardly from the horizontal surface, and a width of the second gap feature is greater than a width of the first gap feature.

In some embodiments, the method further includes depositing the film in the second gap feature during the deposition process, and the first top surface of the film on the first gap feature is higher than a second top surface of the film on the second gap feature.

In some embodiments, the method further includes forming a second air gap in the film in the second gap feature during the curing process, and the height of the first air gap is greater than the height of the second air gap.

In some embodiments, the method further includes depositing the film in the second gap feature during the deposition process, and the first top surface of the film on the first gap feature is flush with a second top surface of the film on the second gap feature.

In some embodiments, the method further includes forming a second air gap in the film in the second gap feature during the curing process, and the height of the first air gap is equal to the height of the second air gap.

In some embodiments, the method further includes performing an annealing process after the curing process to facilitate the formation of the first air gap.

In some embodiments, the temperature of the annealing process is about 350 °C to about 500 °C.

In some embodiments, the thickness of a sidewall of the film between the first air gap and the substrate is about 1 nm to about 10 nm.

In some embodiments, the deposition process includes providing a precursor to the reaction chamber, and the precursor comprises hexamethyltrisilazane (HMCTS), hexamethyldisilazane (HMDS), tetramethyldivinyldisilazane (TMDVDS), tetramethyldisilazane (TMDS), tetrasilyl-silanediamine, methyltrimethoxysilane (MTMS), or a combination thereof.

According to some embodiments of the present disclosure, an apparatus for forming a film having an air gap is provided. The apparatus includes one or more reaction chambers configured to form a film on a substrate, each reaction chamber including two or more stations; a heating system configured to control a first station temperature independently from a second station temperature in the one or more reaction chambers; a pressure system configured to maintain a pressure in the two or more stations; an annealing chamber configured to perform an annealing process on the substrate; and a controller configured to control the one or more reaction chambers, the heating system, the pressure system, and the annealing chamber so as to perform the methods of some embodiments of the present disclosure.

### BRIEF DESCRIPTION OF THE DRAWINGS

Embodiments of the present disclosure can be best understood from the following detailed description in conjunction with the accompanying drawings. It should be noted that, in accordance with the common practice in the industry, various features are not drawn to scale. In fact, the dimensions of the various elements may be arbitrarily increased or reduced to clearly illustrate the features of the embodiments of the present disclosure. It should also be noted that the drawings illustrate typical embodiments of the present disclosure. The drawings should not be considered as limitation of the present disclosure. The present disclosure may also be applied to other embodiments.

FIG. 1 illustrates a schematic method for forming a film having an air gap, according to some embodiments of the present disclosure.

FIG. 2 illustrates a schematic cross-section view of a substrate having a gap feature, according to some embodiments of the present disclosure.

FIG. 3 illustrates a schematic cross-section view of a substrate having a gap feature, according to some embodiments of the present disclosure.

FIG. 4A illustrates a schematic cross-section view of a substrate having a gap feature, according to some embodiments of the present disclosure.

FIG. 4B illustrates a schematic cross-section view of a substrate having a gap feature, according to some embodiments of the present disclosure.

FIG. 5A illustrates a schematic cross-section view of a substrate having a first gap feature and a second gap feature, according to some embodiments of the present disclosure.

FIG. 5B illustrates a schematic cross-section view of a substrate having a first gap feature and a second gap feature, according to some embodiments of the present disclosure.

FIG. 6 illustrates a schematic apparatus, according to some embodiments of the present disclosure.

FIG. 7 illustrates a schematic apparatus, according to some embodiments of the present disclosure.

### DETAILED DESCRIPTION

The following disclosure provides many different embodiments, or examples, for implementing different features of the described subject matter. Specific examples of elements and arrangements are described below to simplify the present description. These are, of course, merely examples and are not intended to be limiting. For example, a formation of a first feature over or on a second feature in the description that follows may include embodiments in which the first and second features are formed in direct contact, and may also include embodiments in which additional features may be formed between the first and second features, such that the first and second features may not be in direct contact. Furthermore, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that the ordinal numbers used in the present disclosure, such as the terms “first,” “second,” “third,” etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. The claims and the specification may not use the same terms. For example, the first element in the specification may refer to the second element in the claims.

In the following descriptions, terms “about” and “substantially” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. The values given in the present disclosure are approximate. That is, without specifying terms the terms “about” and “substantially,” the meaning of “about” and “substantially” can still be implied.

Some embodiments of the present disclosure are described below. Additional steps or operations may be provided before, during, and/or after the steps or operations described in these embodiments. Some of the steps or operations described may be replaced or deleted in different embodiments. In addition, it should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

In the present disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, a multi-port injection system, other gas distribution device, or the like, can be used for, e.g., sealing the reaction space, and can include a seal gas, such as a noble gas. In some cases, the term “precursor” can refer to a compound that participates in the chemical reaction that produces another compound, and particularly to a compound that constitutes a film matrix or a main skeleton of a film. The term “reactant” can be used interchangeably with the term “precursor.”

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

For example, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

A non-limiting example of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

As used herein, “atomic layer deposition,” abbreviated as “ALD,” refers to a vapor deposition process in which deposition cycles, such as a plurality of consecutive deposition cycles, are conducted in a reaction space (i.e., one or more reaction chambers). Generally, in ALD processes, during each deposition cycle, a precursor is introduced into a reaction space and is adsorbed onto a substrate surface, which may include a previously deposited material from a previous ALD cycle or other materials, forming maximally one monolayer of the precursor that does not readily react with additional excess precursor (i.e., a self-limiting reaction). Thereafter, in some cases, another precursor or a reactant may be introduced into the reaction space to convert the chemisorbed precursor to the desired material on the substrate surface. Other reaction steps may be included in the deposition cycle. ALD may occur by a thermal process (thermal ALD), where the reactions are promoted by increasing the temperature of the substrate relevant to ambient temperature; and/or by a plasma enhanced process (PEALD), where the reactions are promoted through the use of energetic plasma species. ALD, as used herein, may also be meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of reactants.

As used herein, “chemical vapor deposition,” abbreviated as “CVD,” refers to a vapor deposition process in which a film is deposited on a substrate by exposing its surface to one or more gaseous precursors and reactants, which react and/or decompose on the substrate surface to form the film. The precursors and/or reactants can be provided simultaneously to the reaction space, or in partially or completely separated pulses. In some embodiments, the precursors and/or reactants are provided until a layer having a desired thickness is deposited. In some embodiments, a cyclic CVD process can be used with multiple cycles to deposit a thin film having a desired thickness. In cyclic CVD processes, the precursors and/or reactants may be provided to the reaction space in pulses that do not overlap, or that partially or completely overlap. CVD may occur by a thermal process (thermal CVD), where the reaction(s) are promoted by increasing the temperature of the substrate relevant to ambient temperature; or by a plasma enhanced process (PECVD), where the reaction(s) are promoted through the use of energetic plasma species.

As used herein, the term “film” and/or “layer” can refer to any continuous or non-continuous structures and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. Alternatively, a film or layer may consist entirely of isolated islands.

In the present disclosure, the terms “including,” “constituted by” and “having” refer independently to “typically or broadly comprising,” “comprising,” “consisting essentially of,” or “consisting of” in some embodiments. It shall be understood that when a composition, method, device, etc. is said to comprise certain features, it means that it includes those features, and that it does not necessarily excludes the presence of other features, as long as they do not render the claim unworkable. This notwithstanding, the wording “comprises” includes the meaning of “consists of,” i.e., the case when the composition, method, device, etc. in question only includes the features, components, and/or steps that are listed, and does not contain any other features, components, steps, etc.

The term “carrier gas” as used herein may refer to a gas that is provided to a reaction chamber together with one or more precursors. For example, a carrier gas may be provided to the reaction chamber together with one or more of the precursors used herein. Exemplary carrier gasses include N₂, H₂, and noble gasses such as He, Ne, Kr, Ar, and Xe.

As opposed to a carrier gas, a purge gas may be provided to a reaction chamber separately, i.e., not together with one or more precursors. This notwithstanding, gasses which are commonly used as carrier gas may also be used as a purge gas, even within the same process. For example, in a cyclic deposition-etch process, N₂ used as a carrier gas may be provided together with one or more precursors during deposition pulses, and N₂ used as a purge gas may be used to separate deposition and etch pulses. Hence, it is the manner of how a gas is provided to the reaction chamber that determines whether it serves as a purge gas or a carrier gas in a specific context. Thus, as used herein, the term “purge” may refer to a procedure in which an inert or substantially inert gas is provided to a reaction chamber in between two pulses of gasses which react with each other. For example, a purge, e.g., using nitrogen gas, may be provided between a precursor pulse and a reactant pulse, thus avoiding or at least minimizing gas phase interactions between the precursor and the reactant. It shall be understood that a purge can be effected either in time or in space, or both. For example, in the case of temporal purges, a purge step can be used, e.g., in the temporal sequence of providing a first precursor to a reaction chamber, providing a purge gas to the reaction chamber, and providing a second precursor to the reaction chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied.

As used herein, “station” refers broadly to a location that can contain a substrate so that a process may be performed on the substrate in the station. A station can thus refer to a reactor, or a portion or a reactor, or a reaction space or reaction chamber within a reactor. In some embodiments, stations in accordance with embodiments herein are in “gas isolation” from each other or are configured to be in gas isolation while a substrate is processed inside the station. In some embodiments, the stations are in gas isolation by way of physical barriers but not gas bearings or gas curtains. In some embodiments, the stations are in gas isolation by way of physical barriers in conjunction with gas bearings and gas curtains. In some embodiments, after or concurrently with the placement of a substrate in a particular station, that substrate is placed in gas isolation from the other stations (so that process steps can be performed in that station), and after the substrate has processed in the station, the station is brought out of gas isolation, and the substrate can be removed from the station and positioned in an intermediate space. Substrates from multiple different stations can be placed in a shared intermediate space for movement from station to station. The stations can be placed in gas isolation, for example, by a physical barrier. In some embodiments, the stations are not placed in gas isolation. In some embodiments, one or more stations includes a heating and/or cooling system, so that different precursors in different stations can process substrates at different temperatures at the same time. As such, in some embodiments, an entire first station is at a lower or higher temperature than an entire second station, or a first station includes a susceptor that is at a lower or higher temperature than a susceptor in a second station, and/or a first precursor is flowed into a first station while a second precursor is flowed into a second station at a lower or higher temperature than the first station.

In some embodiments, the stations are separated from each other by solid materials, and are not separated from each other by gas bearings or gas curtains. In some embodiments, the stations are separated from each other by solid materials or gas curtains and are not separated from each other by gas bearings. In some embodiments, the stations are separated from each other by solid materials or gas bearings and are not separated from each other by gas curtains. Optionally, the physical barrier can move in conjunction with a moving stage that shuttles substrates between the stations and the intermediate space, so that the physical barrier places the station in gas isolation at the same time (or slightly before or slightly after) the substrate is placed in that station. Optionally the physical barrier can be used in conjunction with a gas barrier, for example to fill some gaps left by the physical barrier. In some embodiments, a physical barrier is provided, but a gas barrier or gas curtain does not.

In some embodiments, a station includes a module or chamber of a reactor, so that each station includes a separate chamber or module. In some embodiments, a station includes a portion of a reaction chamber which can be placed in gas isolation from other portions of the reaction chamber by positioning a wall, a gas curtain or a gas bearing between the stations. Optionally, a given station is completely enclosed by one or more walls, gas curtains, gas bearings, or a combination of any of these items. However, in some embodiments, the stations are not separated.

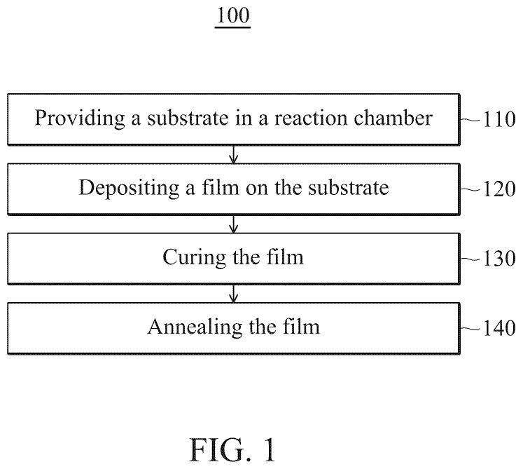

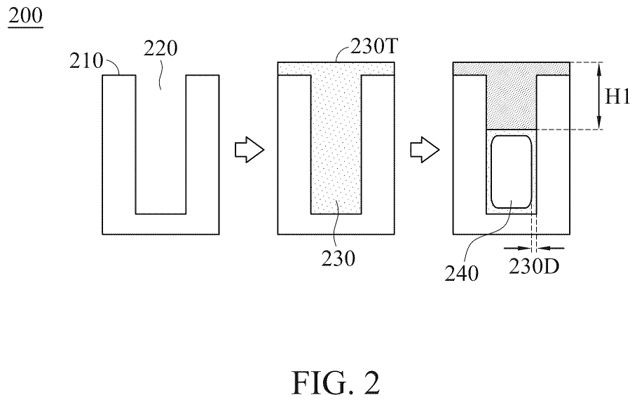

Referring to FIGS. 1 and 2, FIG. 1 illustrates a schematic method 100 for forming a film having an air gap, and FIG. 2 illustrates a schematic cross-section view of a substrate 200 having a gap feature 220 according to some embodiments of the present disclosure. The method 100 includes providing the substrate 200 in a reaction chamber (step 110). The substrate 200 includes a horizontal surface 210 and the gap feature 220 extending downwardly from the horizontal surface 210. The method 100 includes depositing a film 230 on the substrate 200 (step 120). The film 230 includes a top surface 230T on the gap feature 220. The method 100 includes curing the film 230 to form an air gap 240 in the film 230 (step 130). The method 100 further includes an optional step: annealing the film 230 (step 140).

The sequence of the steps in the method 100 is only an example. The sequence may be varied in other embodiments. In some embodiments, other steps may be provided in the method. For example, in some embodiments, there is an additional step for providing a plasma during the deposition process. For example, in some embodiments, there is an additional step for providing a purge gas.

In some embodiments, the flowable film 230 may be formed in a first station (deposition station) of a reaction chamber through a flowable deposition process (e.g., flowable CVD) and may be cured (i.e., post-deposition treatment) in a second station of the reaction chamber. In some embodiments, the deposition of the flowable film 230 may be performed by flowing one or more precursors in a gaseous phase. One or more precursors may be formed into polymers. In some embodiments, one or more precursors may be selected from a list consisting of silylamines, silazanes, cyclosilazanes, and silicon alkylamines. For example, one or more precursors may include hexamethyltrisilazane (HMCTS), hexamethyldisilazane (HMDS), tetramethyldivinyldisilazane (TMDVDS), tetramethyldisilazane (TMDS), tetrasilyl-silanediamine, methyltrimethoxysilane (MTMS), or a combination thereof.

In some embodiments, one or more precursors in a gaseous (viscous) phase flow into gaps of a substrate which may be, for example, a silicon wafer. As a result, one or more precursors may seamlessly fill the gaps in a bottom-up manner. A flowable film may be temporarily obtained when the gaseous precursors are polymerized by a plasma, wherein gaseous precursors (e.g., monomers) are activated by energy provided by a plasma, thereby initiating polymerization. The film shows temporarily flowable behavior when the film is deposited on the surface and in the gaps of the substrate. Subsequent processing steps (for example, a curing step) may be used to solidify the polymer.

In some embodiments, the deposition process includes the use of a radio frequency (RF) plasma and pulsed precursor flow. In some embodiments, process parameters may be changed to achieve high enough partial pressure during the entire RF-on period for polymerization to progress, and to provide sufficient energy to activate the reaction. In some embodiments, temperature and pressure may be controlled for polymerization and set above the melting point and below the boiling point of the flowable phase. In some embodiments, one or more precursors may be introduced into a reaction chamber, and one or more process gases may also be introduced into the reaction chamber. The process gasses may include a co-reactant, a noble gas, a carrier gas, a dilution gas, or a combination thereof. For example, one or more process gases may include Ar, He, N₂, H₂, NH₃, O₂, or a combination thereof. In some embodiments, the process gases and the precursors may be introduced simultaneously. In some embodiments, the precursors may be introduced before or after the process gases. In some embodiments, the RF plasma may be maintained before, during, or after introduction of the precursors and/or process gases. It will be understood that when the method described above is performed in a sequential manner, i.e., cyclically, a small amount of material may be deposited each cycle and the sequence of steps may be repeated until a layer with a desired thickness is obtained. In some embodiments, the method is performed cyclically and one or more steps are separated by purge gas pulses.

In some embodiments, the method above involves providing the precursors intermittently to the reaction chamber, and continuously providing the plasma. In some embodiments, the method above involves providing the precursors intermittently to the reaction chamber, and intermittently providing the plasma.

Process parameters may include, for example, pressure and temperature in a reaction chamber. Without being bound by theory or any particular mode of operation, it is believed that the deposited material desirably remains viscous or liquid throughout the deposition process and should not readily solidify or evaporate. It is further believed that under desirable reaction conditions, the vapor pressure of the liquid phase, but not that of the precursors, should be lower than a total pressure. Thus, it is believed that the pressure and temperature should be maintained at conditions under which the flowable film exists as a liquid, and the precursor exist as a gas.

In some embodiments, the pressure in the reaction chamber may be maintained at a pressure between about 300 Pa and about 2800 Pa. For example, the pressure in the reaction chamber may be maintained at about 300 Pa, about 350 Pa, about 400 Pa, about 450 Pa, about 500 Pa, about 550 Pa, about 600 Pa, about 650 Pa, about 700 Pa, about 750 Pa, about 800 Pa, about 850 Pa, about 900 Pa, about 950 Pa, about 1000 Pa, about 1050 Pa, about 1100 Pa, about 1150 Pa, about 1200 Pa, about 1250 Pa, about 1300 Pa, about 1350 Pa, about 1400 Pa, about 1450 Pa, about 1500 Pa, about 1550 Pa, about 1600 Pa, about 1650 Pa, about 1700 Pa, about 1750 Pa, about 1800 Pa, about 1850 Pa, about 1900 Pa, about 1950 Pa, about 2000 Pa, about 2050 Pa, about 2100 Pa, about 2150 Pa, about 2200 Pa, about 2250 Pa, about 2300 Pa, about 2350 Pa, about 2400 Pa, about 2450 Pa, about 2500 Pa, about 2550 Pa, about 2600 Pa, about 2650 Pa, about 2700 Pa, about 2750 Pa, about 2800 Pa, or any value between any of the aforementioned values.

In some embodiments, the temperature in the reaction chamber may be maintained at a temperature lower than about 300 °C. For example, the temperature in the reaction chamber may be maintained at about 50 °C, about 55 °C, about 60 °C, about 65 °C, about 70 °C, about 75 °C, about 80 °C, about 85 °C, about 90 °C, about 95 °C, about 100 °C, about 105 °C, about 110 °C, about 115 °C, about 120 °C, about 125 °C, about 130 °C, about 135 °C, about 140 °C, about 145 °C, about 150 °C, about 155 °C, about 160 °C, about 165 °C, about 170 °C, about 175 °C, about 180 °C, about 185 °C, about 190 °C, about 195 °C, about 200 °C, about 205 °C, about 210 °C, about 215 °C, about 220 °C, about 225 °C, about 230 °C, about 235 °C, about 240 °C, about 245 °C, about 250 °C, about 255 °C, about 260 °C, about 265 °C, about 270 °C, about 275 °C, about 280 °C, about 285 °C, about 290 °C, about 295 °C, about 300 °C, or any value between the aforementioned values.

In some embodiments, the RF power provided to the reaction chamber may be between about 20 W and about 1000 W. For example, in some embodiments, the RF power provided to the reaction chamber may be at about 20 W, about 40 W, about 60 W, about 80 W, about 100 W, about 120 W, about 140 W, about 160 W, about 180 W, about 200 W, about 220 W, about 240 W, about 260 W, about 280 W, about 300 W, about 320 W, about 340 W, about 360 W, about 380 W, about 400 W, about 420 W, about 440 W, about 460 W, about 480 W, about 500 W, about 520 W, about 540 W, about 560 W, about 580 W, about 600 W, about 620 W, about 640 W, about 660 W, about 680 W, about 700 W, about 720 W, about 740 W, about 760 W, about 780 W, about 800 W, about 820 W, about 840 W, about 860 W, about 880 W, about 900 W, about 920 W, about 940 W, about 960 W, about 980 W, about 1000 W, or any value between the aforementioned values.

The precursors and process gases may be provided to the reaction chamber at a volumetric flow rate of about 0.1 standard liter per minute (SLM) to about 10 SLM. For example, the precursors and process gases may be provided to the reaction chamber at a volumetric flow rate of about 0.1 SLM, about 0.5 SLM, about 1 SLM, about 1.5 SLM, about 2 SLM, about 2.5 SLM, about 3 SLM, about 3.5 SLM, about 4 SLM, about 4.5 SLM, about 5 SLM, about 5.5 SLM, about 6 SLM, about 6.5 SLM, about 7 SLM, about 7.5 SLM, about 8 SLM, about 8.5 SLM, about 9 SLM, about 9.5 SLM, about 10 SLM, about 10.5 SLM, about 11 SLM, about 11.5 SLM, about 12 SLM, about 12.5 SLM, about 13 SLM, about 13.5 SLM, about 14 SLM, about 14.5 SLM, about 15 SLM, about 15.5 SLM, about 16 SLM, about 16.5 SLM, about 17 SLM, about 17.5 SLM, about 18 SLM, about 18.5 SLM, about 19 SLM, about 19.5 SLM, about 20 SLM, or any value in between the aforementioned values.

In some embodiments, the curing process may include a plasma curing process, UV curing process, another suitable curing process, or a combination thereof.

In the embodiment where the curing process is a plasma curing process, the plasma may be H₂ plasma. As shown in FIG. 2, the plasma curing process includes a curing depth H1 extending from the top surface 230T of the film 230 to the gap feature 220. In some embodiments, the curing depth H1 is about 2 nm to about 10 nm.

In the embodiment where the curing process is a UV curing process, the UV curing process includes an excimer molecule. In some embodiments, the excimer molecule includes Xe₂, NeF, Ar₂, Kr₂, F₂, ArBr, ArCl, KrI, ArF, KrBr, KrCl, or a combination thereof. In some embodiments, the wavelength of the UV curing process may be between 100 nm and 250 nm, between 110 nm and 240 nm, between 120 nm and 230 nm, between 130 nm and 220 nm, between 140 nm and 210 nm, between 150 nm and 200 nm, between 160 nm and 190 nm, or between 170 nm and 180 nm. For example, the wavelength of the UV curing process may be 108 nm, 126 nm, 146 nm, 158 nm, 165 nm, 172 nm, 175 nm, 190 nm, 193 nm, 207, or 222 nm. In one embodiment, the excimer molecule may be Xe₂, and the wavelength of the UV curing process may be 172 nm. As shown in FIG. 2, the UV curing process includes a curing depth H1 extending from the top surface 230T of the film 230 to the gap feature 220. In some embodiments, the curing depth H1 is about 50 nm to about 100 nm.

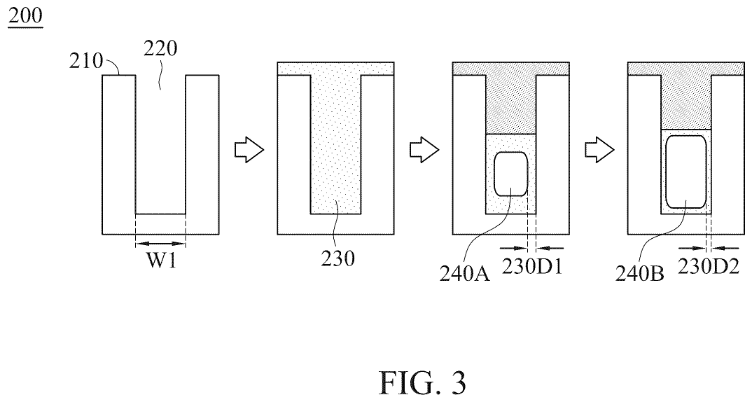

Still referring to FIG. 2, after the film 230 is cured, and a non-cured bottom portion of the film 230 desorbs, resulting the formation of the air gap 240. In some embodiments, the thickness 230D of a sidewall of the film 230 between the air gap 240 and the substrate 200 may be about 1 nm to about 10 nm. In the embodiment shown in FIG. 2, the width the gap feature 220 is less than 50 nm, the air gap 240 with desired dimension can be formed after the curing process. However, referring to FIG. 3, if the width W1 of the gap feature 220 is greater than 50 nm, an annealing process may be performed after the curing process to obtain the air gap 240 with desired dimension. In particular, in the embodiment shown in FIG. 3, the air gap 240A is formed in the film 230 after the curing process. However, the air gap 240A is too small, which means that the thickness 230D1 of the sidewall of the film 230 between the air gap 240A and the substrate 200 is too thick. Therefore, the annealing process is performed to facilitate to cure the film 230 and remove the non-cured portion of the film 230, resulting the formation of the air gap 240B. In some embodiments, the thickness 230D2 of the sidewall of the film 230 between the air gap 240B and the substrate 200 may be about 1 nm to about 10 nm.

In some embodiments, the annealing process may be a rapid thermal annealing (RTA) process. In some embodiments, the substrate is heated rapidly by exposure to infrared (IR) radiation. The exposure time of the annealing process may be between about 0.1 second (s) and about 10 s. For example, in some embodiments, the exposure time may be about 0.1 s, about 0.2 s, about 0.3 s, about 0.4 s, about 0.5 s, about 0.6 s, about 0.7 s, about 0.8 s, about 0.9 s, about 1 s, about 1.1 s, about 1.2 s, about 1.3 s, about 1.4 s, about 1.5 s, about 1.6 s, about 1.7 s, about 1.8 s, about 1.9 s, about 2 s, about 2.1 s, about 2.2 s, about 2.3 s, about 2.4 s, about 2.5 s, about 2.6 s, about 2.7 s, about 2.8 s, about 2.9 s, about 3 s, about 3.1 s, about 3.2 s, about 3.3 s, about 3.4 s, about 3.5 s, about 3.6 s, about 3.7 s, about 3.8 s, about 3.9 s, about 4 s, about 4.1 s, about 4.2 s, about 4.3 s, about 4.4 s, about 4.5 s, about 4.6 s, about 4.7 s, about 4.8 s, about 4.9 s, about 5 s, about 5.1 s, about 5.2 s, about 5.3 s, about 5.4 s, about 5.5 s, about 5.6 s, about 5.7 s, about 5.8 s, about 5.9 s, about 6 s, about 6.1 s, about 6.2 s, about 6.3 s, about 6.4 s, about 6.5 s, about 6.6 s, about 6.7 s, about 6.8 s, about 6.9 s, about 7 s, about 7.1 s, about 7.2 s, about 7.3 s, about 7.4 s, about 7.5 s, about 7.6 s, about 7.7 s, about 7.8 s, about 7.9 s, about 8 s, about 8.1 s, about 8.2 s, about 8.3 s, about 8.4 s, about 8.5 s, about 8.6 s, about 8.7 s, about 8.8 s, about 8.9 s, about 9 s, about 9.1 s, about 9.2 s, about 9.3 s, about 9.4 s, about 9.5 s, about 9.6 s, about 9.7 s, about 9.8 s, about 9.9 s, about 10 s, or any value between any of the aforementioned values.

In some embodiments, the annealing process may be performed at a temperature between about 80 °C and about 1000 °C. In some embodiments, the annealing process may be performed at about 80 °C, about 105 °C, about 130 °C, about 155 °C, about 180 °C, about 205 °C, about 230 °C, about 255 °C, about 280 °C, 300 °C, about 325 °C, about 350 °C, about 375 °C, about 400 °C, about 425 °C, about 450 °C, about 475 °C, about 500 °C, about 525 °C, about 550°C, about 575 °C, about 600 °C, about 625 °C, about 650 °C, about 675 °C, about 700 °C, about 725 °C, about 750 °C, about 775 °C, about 800 °C, about 825 °C, about 850 °C, about 875 °C, about 900 °C, about 925 °C, about 950 °C, about 975 °C, about 1000 °C, or any value between the aforementioned values. In some embodiments, a higher temperature of the annealing process may correspond to a lower exposure time of the annealing process.

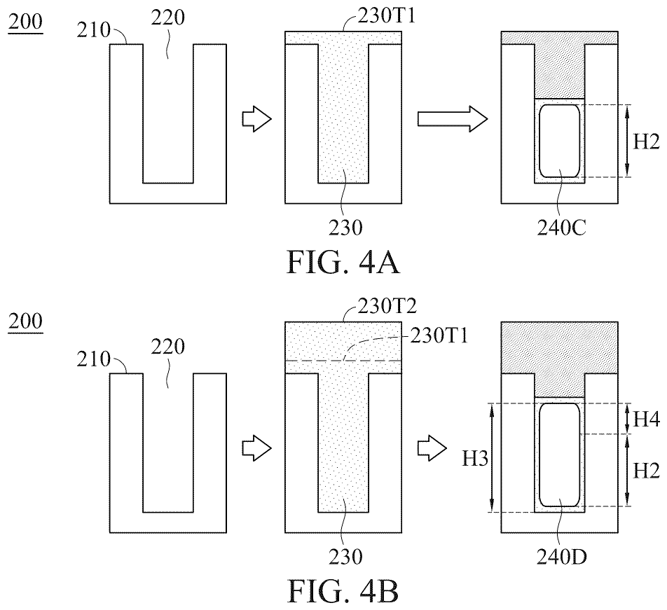

Referring to FIGS. 4A and 4B, the position of the air gap can be controlled based on the amount of deposition of the film. In the embodiment shown in FIG. 4A, the film 230 has a first top surface 230T1 on the gap feature 220, and the air gap 240C has a first height H2 after the curing process. In the embodiment shown in FIG. 4B, before the curing process, the film 230 is further deposited to reach the second top surface 230T2 on the gap feature 220. The second top surface 230T2 is higher than the first top surface 230T1. After the curing process, the air gap 240D has a second height H3, and the second height H3 is higher than the first height H2. Therefore, the position of the air gap is raised upwardly by the height H4.

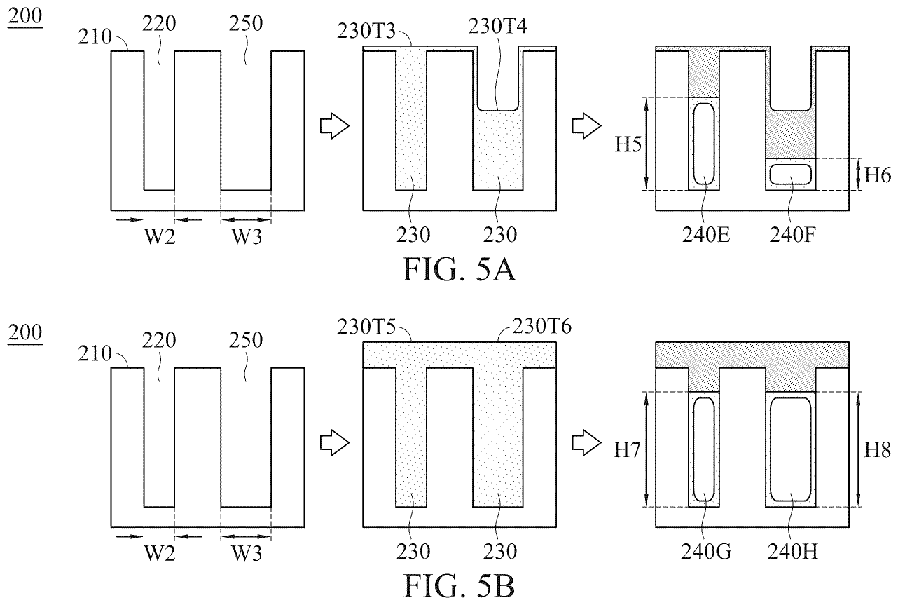

Referring to FIGS. 5A and 5B, the positions of air gaps in different gap features can be controlled by the amount of deposition of the film. In the embodiments shown in FIGS. 5A and 5B, the substrate 200 further includes a second gap feature 250 extending downwardly from the horizontal surface 210, and the width W3 of the second gap feature 250 is greater than the width W2 of the first gap feature 220. In the embodiment shown in FIG. 5A, the film 230 is deposited to have the first top surface 230T3 on the first gap feature 220 and the second top surface 230T4 on the second gap feature 250. The first top surface 230T3 is higher than the second top surface 230T4. After the curing process, the air gap 240E in the first gap feature 220 has the height H5, the air gap 240F in the second gap feature 250 has the height H6, and the height H5 is higher than the height H6. In the embodiment shown in FIG. 5B, before the curing process, the film 230 is over-deposited. The first top surface 230T5 of the film 230 on the first gap feature 220 is flush with the second top surface 230T6 of the film 230 on the second gap feature 250. After the curing process, the height H7 of the air gap 240G is equal to the height H8 of the air gap 240H.

According to some embodiments, a multi-process chamber apparatus having one or more low-temperature deposition stations and one or more treatment stations may be used. In some embodiments, a multi-process quadruple-chamber-module (QCM) apparatus may be used, in which one or more low temperature deposition stations and one or more treatment (e.g., plasma and/or UV curing) stations are used. For example, some apparatuses may include two deposition stations and two treatment stations. In some embodiments, some apparatuses may include four treatment stations, which may be configured to heat substrates to different temperatures. In some embodiments, an a-CH, SiCN, SiN, SiON, SiCO, SiCOH, SiCNH, SiCH, SiNH, or SiCON gap fill may be utilized. Thus, although the embodiments herein a primarily described in relation to SiCN and/or SiN deposition, some embodiments herein may be broadly applicable to various process chemistries.

In some embodiments, a multi-process chamber apparatus may include two or more stations for performing a flowable deposition and post-deposition treatment (e.g., plasma and UV curing) of a substrate. In some embodiments, the multi-process chamber apparatus may include a dual system gas-delivery and temperature control system, such that each station can be independently heated and different gases can be delivered to each station simultaneously. In some embodiments, each station of the multi-process chamber apparatus may include a heater for heating the station independently from other stations of the multi-process chamber module. In some embodiments, the heater may include an aluminum nitride (AlN) ceramic heater or an anodized aluminum heater. In some embodiments, the heater may include one or more heat lamps for transmitting IR radiation to a surface of the substrate.

In some embodiments, the multi-process chamber apparatus may include an integrated, single system exhaust and pump system, such that all stations can be maintained at a synchronized pressure simultaneously. Furthermore, the multi-process chamber apparatus may include a single system radio frequency power source for providing radio frequency power to the stations. In some embodiments, radio frequency power may be provided independently to the stations.

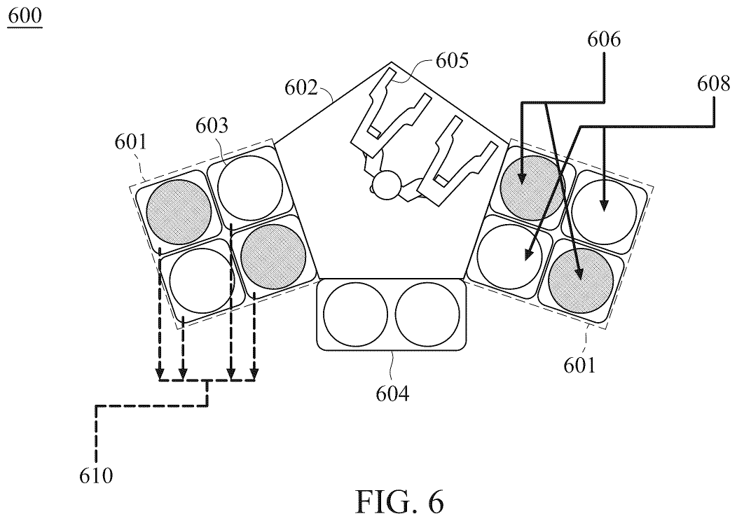

Referring to FIG. 6, FIG. 6 illustrates a schematic apparatus 600 according to some embodiments of the present disclosure. In some embodiments, the apparatus 600 may be a multi-process chamber apparatus. The apparatus 600 may include one or more reaction chambers 601 (process chambers), each reaction chamber including one or more stations 603 in gas isolation from the other stations. In some embodiments, a spider 605 may move the substrate from reaction chamber-to-reaction chamber. An end effector stationed in a wafer handling chamber 602 (WHC) can add and remove substrates from the spider (in communication with the reaction chambers) and/or a load lock chamber 604 (LLC). As noted above, the multi-process chamber module may include a dual heating system including independent heating systems 606, 608. In some embodiments, the heating system 606 may heat and/or cool one or more of the stations 603 independently from the heating system 608 to a first temperature. Similarly, the heating system 608 may heat and/or cool one or more of the other stations 603 independently from the heating system 606 to a second temperature, different from the first temperature. This configuration enables different simultaneous processes in different stations, such as one or more deposition processes and one or more curing processes. The apparatus 600 may also include a pressure system 610 including an exhaust and pump system. In some embodiments, the pressure system 610 may be connected to all stations 603 in a reaction chamber 601, so that the same chamber pressure can be maintained in all of the stations 603 in the reaction chamber 601. In some embodiments, the stations 603 are not sealed from each other. In some embodiments, this lack of station separation allows for a less complex design, easier and faster wafer handling between stations, and a shared pressure system 610, such that deposition stations and curing stations can be maintained at the same pressure simultaneously.

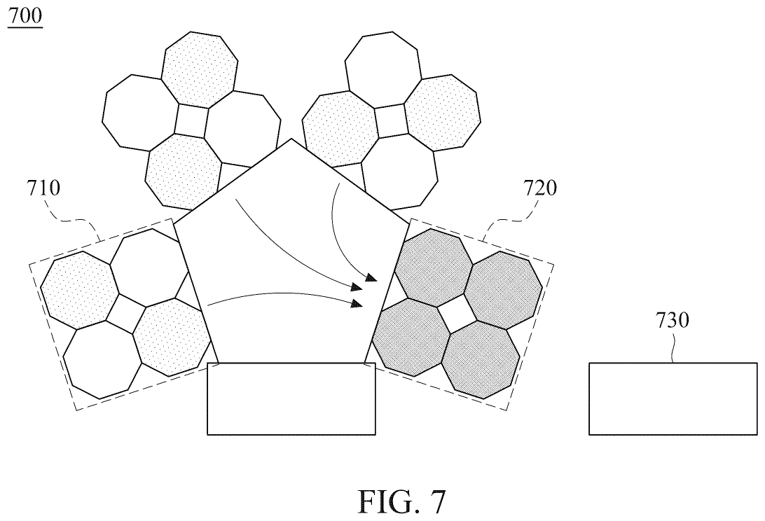

Referring to FIG. 7, FIG. 7 illustrates a schematic apparatus 700 according to some embodiments of the present disclosure. In some embodiments, the apparatus 700 may be a multi-process quadruple-chamber-module (QCM) apparatus. In FIG. 7, the apparatus 700 has three QCMs 710 (process QCMs) for deposition processes and has one QCM 720 (annealing QCM) for annealing as described herein. In some embodiments, each QCM 710 may be the reaction chamber 601 of the apparatus 600. After completing a deposition process, the substrate may be transferred from the process QCM to the annealing QCM. In the embodiment shown in FIG. 7, one QCM is for annealing. It should be understood that the QCM is not necessary in some embodiments. For example, the annealing chamber may have 1 station, 2 stations, 3 stations, 4 stations, 5 stations, 6 stations, or more.

According to some embodiments, a station for deposition that is in gas communication with a precursor source is provided, such that a precursor can be flowed into the station. In some embodiments, the apparatus 700 may further include a controller 730 configured to control the movement of the substrate from station to station, the flow of precursors and process gases into stations, and/or the purging of stations. Different process gases can be contacted with a substrate at different temperatures that are appropriate for each particular precursor. The controller 730 is configured to be in communication with various power sources, heating systems, pumps, robotics, and gas flow controllers or valves, and is configured to carry out the methods of some embodiments of the present disclosure.

In some embodiments, a precursor in a station is delivered via a showerhead. Optionally, the showerhead includes a heated showerhead so as to provide the precursor to the station at a desired temperature or range of temperatures. In some embodiments, the heated showerhead provides the process gas to the station at or near the temperature at which the precursor contacts the substrate. Optionally, the showerhead includes a vacuum exhaust scavenger around its perimeter to capture excess precursor and to minimize the amount of precursor that is potentially available to participate in CVD reactions with other gases. In some embodiments, precursors are contained within stations (and/or precursor source lines and/or purge lines) but are not permitted to enter any spaces between the stations.

It is noted that if two different stations include two different processes, different station conditions, for example different temperatures can be maintained in the different stations. For example, a first station can be at a first temperature optimized for a first process at the first station, and a second station can be at a second temperature optimized for a second process at the second station. As such, in some embodiments, the whole first station is at a different temperature than the whole second station. In some embodiments, the whole first station is at a different temperature than the whole second station, but the two stations are at the same pressure.

Optionally, a station is further in gas communication with a purge gas source and/or a vacuum, so that the station can be purged. For example, according to some embodiments, after a substrate is contacted with a precursor at a first station (but before the substrate is moved to a second station), the station can be purged while the substrate remains in the first station so as to minimize or eliminate the possibility of any lingering precursor being transported to the second station along with the substrate.

Optionally, in some embodiments, one or more stations include a susceptor on which a substrate can be placed. The susceptor can be heated or cooled, and thus can be configured to heat or cool a substrate to a suitable temperature. As such, in some embodiments, a susceptor in the first station is heated or cooled to a first temperature, while a susceptor in the second station is heated or cooled to a second temperature. Furthermore, in some embodiments, the susceptor can heat or cool the substrate for different durations so as to allow the substrate to reach the appropriate temperature. In some embodiments, cooling and/or heating susceptors may be necessary to maintain the large temperature differences between deposition stations and anneal stations. Optionally, the susceptor can have a lower mass than the substrate, so that the susceptor can be heated or cooled more rapidly than the substrate. In other embodiments, the susceptor may have a larger mass than the substrate, such that the substrate can be heated or cooled faster than the susceptor. Optionally, the susceptor does not move from station to station. Optionally, the susceptor comprises a heated and/or cooled susceptor. In some embodiments, the susceptor is at an appropriate temperature for deposition of a precursor before the substrate is placed on the susceptor. In some embodiments, the susceptor is heated to an appropriate temperature for deposition of a precursor after the substrate is placed on the susceptor.

In some embodiments of the present disclosure, the flowable film is cured through a plasma curing process (H₂ plasma). Then, an annealing process is performed at temperature of about 400 °C.

In some embodiments of the present disclosure, the flowable film is cured through a UV curing process (Xe excimer with a wavelength of 172 nm). Then, an annealing process is performed at temperature of about 400 °C.

In some embodiments of the present disclosure, because the curing depth (i.e., about 2 nm to about 10 nm) of the plasma curing process is less than the curing depth (i.e., about 50 nm to about 100 nm) of the UV curing process, the top of the air gap formed through the plasma curing process is higher than the top of the air gap formed through the UV curing process. In addition, the thickness of the sidewall of the flowable film between the air gap and the substrate is about 1 nm to about 10 nm by using the plasma curing process or the UV curing process, which is very thin.

In conventional, an air gap may be formed by a sacrificial film deposition followed by a hard mask deposition and a lateral etching. However, at least three processes are necessary, which is time-consuming. Alternatively, an air gap may be formed by a standard CVD or ALD process. However, it is hard to control size and position of an air gap. According to some embodiments of the present disclosure, a flowable film is deposited followed by a plasma or a UV curing process to form an air gap in the flowable film. The size and position of the air gap can be effectively and precisely controlled by the curing depth of the curing process and the amount of deposition of the flowable film. In addition, with the formation of the air gap having a desired dimension, the thickness of the sidewall of the flowable film between the air gap and the substrate is very small (i.e., about 1 nm to about 10 nm), which ensures an extremely low-k application can be achieved.

Although some embodiments of the present disclosure and their advantages have been described in detail, it should be understood that various changes, substitutions and alterations can be made herein without departing from the spirit and scope of the present disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. A method for forming a film having an air gap, comprising:
providing a substrate in a reaction chamber, wherein the substrate comprises a horizontal surface and a first gap feature extending downwardly from the horizontal surface;
depositing a film on the horizontal surface and in the first gap feature through a deposition process, wherein the film comprises a first top surface on the first gap feature; and
performing a curing process on the film to form a first air gap in the film in the first gap feature.

2. The method for forming a film having an air gap of claim 1, wherein the curing process comprises a plasma curing process.

3. The method for forming a film having an air gap of claim 2, wherein the plasma curing process comprises a H₂ plasma curing process.

4. The method for forming a film having an air gap of claim 2, wherein the plasma curing process comprises a curing depth extending from the first top surface of the film to the first gap feature, and the curing depth is about 2 nm to about 10 nm.

5. The method for forming a film having an air gap of claim 1, wherein the curing process comprises a UV curing process.

6. The method for forming a film having an air gap of claim 5, wherein the UV curing process comprises an excimer molecule.

7. The method for forming a film having an air gap of claim 6, wherein the excimer molecule comprises Xe₂, NeF, Ar₂, Kr₂, F₂, ArBr, ArCl, KrI, ArF, KrBr, KrCl, or a combination thereof.

8. The method for forming a film having an air gap of claim 7, wherein a wavelength of the UV curing process is about 172 nm.

9. The method for forming a film having an air gap of claim 5, wherein the UV curing process comprises a curing depth extending from the first top surface of the film to the first gap feature, and the curing depth is about 50 nm to about 100 nm.

10. The method for forming a film having an air gap of claim 1, wherein the deposition process further comprises depositing the film to reach a second top surface on the first gap feature, and the second top surface is higher than the first top surface.

11. The method for forming a film having an air gap of claim 10, wherein the curing process is performed to increase a height of the first air gap.

12. The method for forming a film having an air gap of claim 1, wherein the substrate further comprises a second gap feature extending downwardly from the horizontal surface, and a width of the second gap feature is greater than a width of the first gap feature.

13. The method for forming a film having an air gap of claim 12, further comprising depositing the film in the second gap feature during the deposition process, wherein the first top surface of the film on the first gap feature is higher than a second top surface of the film on the second gap feature.

14. The method for forming a film having an air gap of claim 13, further comprising forming a second air gap in the film in the second gap feature during the curing process, wherein a height of the first air gap is greater than a height of the second air gap.

15. The method for forming a film having an air gap of claim 12, further comprising depositing the film in the second gap feature during the deposition process, wherein the first top surface of the film on the first gap feature is flush with a second top surface of the film on the second gap feature.

16. The method for forming a film having an air gap of claim 15, further comprising forming a second air gap in the film in the second gap feature during the curing process, wherein a height of the first air gap is equal to a height of the second air gap.

17. The method for forming a film having an air gap of claim 1, further comprising performing an annealing process after the curing process to facilitate the formation of the first air gap.

18. The method for forming a film having an air gap of claim 17, wherein a temperature of the annealing process is about 350 °C to about 500 °C.

19. The method for forming a film having an air gap of claim 1, wherein a thickness of a sidewall of the film between the first air gap and the substrate is about 1 nm to about 10 nm.

20. The method for forming a film having an air gap of claim 1, wherein the deposition process comprises providing a precursor to the reaction chamber, wherein the precursor comprises hexamethyltrisilazane (HMCTS), hexamethyldisilazane (HMDS), tetramethyldivinyldisilazane (TMDVDS), tetramethyldisilazane (TMDS), tetrasilyl-silanediamine, methyltrimethoxysilane (MTMS), or a combination thereof.

21. An apparatus for forming a film having an air gap, comprising:
one or more reaction chambers configured to form a film on a substrate, each reaction chamber comprising two or more stations;
a heating system configured to control a first station temperature independently from a second station temperature in the one or more reaction chambers;
a pressure system configured to maintain a pressure in the two or more stations;
an annealing chamber configured to perform an annealing process on the substrate; and
a controller configured to control the one or more reaction chambers, the heating system, the pressure system, and the annealing chamber so as to perform the method as claimed in claim 1.
